(19) United States
(12) Patent Application Publication
(10) Pub. No.: US 2022/0088718 A1
(43) Pub. Date: Mar. 24, 2022

(54) LASER ANNEALING METHOD AND LASER ANNEALING APPARATUS

(71) Applicant: V TECHNOLOGY CO., LTD., Kanagawa (JP)

(72) Inventor: Michinobu MIZUMURA, Kanagawa (JP)

(73) Assignee: V TECHNOLOGY CO., LTD., Kanagawa (JP)

(21) Appl. No.: 17/421,692

(22) PCT Filed: Jan. 17, 2020
(86) PCT No.: PCT/JP2020/001588

§ 371 Date: Jul. 8, 2021

(30) Foreign Application Priority Data
Jan. 29, 2019 (JP) 2019-012738

(51) Int. Cl. B23K 26/53; B23K 26/073; B23K 26/0622

(52) U.S. Cl. CPC B23K 26/53; B23K 26/0622; B23K 26/073

(57) ABSTRACT

With providing a workpiece that has a seed-crystal zone for microcrystalline silicon at a location proximate to the periphery of and aligned with one of transformation-scheduled regions, each of which is set to coextend with that portion of amorphous silicon which extends over one of gate fins, in a lateral straight line perpendicular to a longitudinal axis of the gate fins, a lateral crystal forming process carries out selective crystal growth by moving a continuous wave laser beam along the lateral straight line with the seed-crystal zone as a starting point to irradiate the amorphous silicon to grow crystalline silicon within the transformation-scheduled region.

### TECHNICAL FIELD

The present invention relates to a laser annealing method and a laser annealing apparatus.

### BACKGROUND

A thin-film transistor (TFT) is used as a switch-device attached to each pixel to actively maintain the pixel state while other pixels are being addressed in a flat panel display (FPD). Amorphous silicon (a-Si) or polycrystalline silicon (p-Si) or the like is being used as a parent material for semiconductor layers of TFTs.

Amorphous silicon is low in mobility, i.e., a semiconductor parameter how quickly an electron can move through a semiconductor. It follows that amorphous silicon cannot meet high mobility needed as a parent material for high-density and highly defined FPDs. Since the mobility of polycrystalline silicon is significantly higher than that of amorphous silicon, polycrystalline silicon is preferrable as a parent material for forming a channel of each switch element used in FPDs. As a known method of forming a polycrystalline silicon film, there is a laser anneal in which an excimer laser annealing (ELA) apparatus incorporating an excimer laser irradiates amorphous silicon with a laser beam to recrystallize amorphous silicon to produce polycrystalline silicon.

There is known a technique about lateral crystal growth of pseudo single crystal silicon in a direction from source to drain to increase the mobility between source and drain in a TFT (see Patent Literature 1). According to a laser anneal disclosed in this Patent Literature 1, amorphous silicon within each drive circuit forming region on a substrate is subject to an excimer laser anneal to produce polycrystalline silicon on the substrate. Subsequently, irradiating the polycrystalline silicon with a line beam of a continuous wave (cw) laser moving relative to the substrate results in forming laterally grown polycrystals spreading over a large area.

### PRIOR ART

### Patent Literature

Patent Literature 1: JP2008-41920 A

### SUMMARY OF THE INVENTION

### Problem to be Solved by the Invention

In the above-mentioned prior art, with a laser beam having a line spot shape, a laser anneal is carried out over a wide area not only in the laser anneal process for lateral crystal growth but also in the excimer laser anneal process that is the pretreatment process prior to the lateral crystal growth. To shape a laser beam having a line spot shape suitable for spreading the laterally grown polycrystalline silicon over the entire display area of an EPD, a laser beam shaper requires a long cylindrical lens. However, along with growing demand for increasing the size of an EPD, it has been financially and technically difficult to fabricate a cylindrical lens long enough to meet the growing demand.

The present invention is made in view of the above-mentioned problem to provide a laser annealing method and a laser annealing apparatus which can form polycrystalline silicon or pseudo single crystalline silicon in selected areas with reduced manufacturing costs.

### Means for Solving the Problem

In order to achieve an object by solving the above-mentioned problem, there is provided, according to one implementation of the present invention, a laser annealing method of transforming amorphous silicon of a film, which overlaps a workpiece including gate fins formed on a substrate in a way such that they extend along a longitudinal axis and are arranged in parallel, to crystalline silicon, the laser annealing method including: providing the workpiece having a seed-crystal zone for microcrystalline silicon at a location proximate to the periphery of and aligned with one of transformation-scheduled regions, each of which is set to coextend with that portion of the amorphous silicon which extends over one of the gate fins, in a lateral straight line perpendicular to the longitudinal axis, and a lateral crystal forming process of carrying out selective crystal growth by moving a continuous wave laser beam along the lateral straight line with the seed-crystal zone as a starting point to irradiate the amorphous silicon to grow crystalline silicon within the transformation-scheduled region.

According to the above-mentioned implementation, it is preferred that, in the lateral crystal forming process, the continuous wave laser beam is a spot laser beam whose incident beam is shaped to result in a beam spot on the surface of the amorphous silicon film.

According to the foregoing implementation, it is preferred that, in the lateral crystal forming process, the beam spot of the continuous wave laser beam moves through the transformation-scheduled regions arranged in the lateral straight line to intermittently irradiate the amorphous silicon.

According to the foregoing implementation, it is preferred to further include a seed crystal forming process in which the seed-crystal zone is laser irradiated with a laser beam for seed crystal formation to grow microcrystalline silicon within the seed-crystal zone prior to the lateral crystal forming process.

According to the foregoing implementation, it is preferred that, in the seed crystal forming process, pulsed laser beams shaped with microlens arrays, each containing multiple micro lenses in a rectangular array, are used for laser irradiation.

There is provided, according to another implementation of the present invention, a laser annealing apparatus for transforming amorphous silicon of a film, which overlaps a workpiece including gate fins formed on a substrate in a way such that they extend along a longitudinal axis and are arranged in parallel, to crystalline silicon, the laser annealing apparatus comprising: a laser source part operative in a continuous wave mode to emit a continuous wave laser beam, and a laser beam irradiation part operative to move the beam spot of the continuous wave laser beam along a lateral straight line perpendicular to the longitudinal axis to grow crystalline silicon within a selected one of transformation-scheduled regions, each of which is set to coextend with that portion of the amorphous silicon which extends over one of the gate fins.

According to the above-mentioned another implementation, it is preferred that the laser beam irradiation part includes a scanner operative to move the laser beam along the lateral straight line.

According to the foregoing another implementation, it is preferred that the laser beam irradiation part is operative to move the beam spot of the laser beam through the transformation-scheduled regions which are aligned in the lateral straight line.

According to the foregoing another implementation, it is preferred that the substrate has a seed-crystal zone for microcrystalline silicon at a location proximate to the periphery of and aligned with one of the transformation-scheduled regions in the lateral straight line, and the laser beam irradiation part is operative to start laser irradiation with the continuous wave laser beam with the seed-crystal zone as a starting point.

### Technical Effects of the Invention

The laser annealing method and apparatus according to the present invention can form polycrystalline silicon or pseudo single crystalline silicon in selected regions required, reducing manufacturing costs because a long cylindrical lens is no longer needed to conduct a laser anneal in selected regions.

### BRIEF DESCRIPTION OF THE DRAWINGS

FIG. 1 is a schematic diagram of a laser annealing apparatus according to an embodiment of the present invention.

FIG. 2 is a cross section of the laser annealing apparatus according to the embodiment of the present invention.

FIG. 3 is a cross section diagram illustrating a seed crystal forming process of a laser annealing method according to an embodiment of the present invention.

FIG. 4 is a plan view of a workpiece on which a pseudo single crystalline silicon film is formed in a lateral crystal forming process of the laser annealing method according to the embodiment of the present invention.

FIG. 5 is a magnified view of an area A of FIG. 4.

FIG. 6 is a flow chart of the laser annealing method according to the embodiment of the present invention.

### MODE FOR CARRYING OUT THE INVENTION

The present subject matter in the form of a laser annealing method and a laser annealing apparatus will be described with reference to the attached figures. Elements are schematically depicted in the drawings, so they are not necessarily to scale and are not intended to portray specific parameters of the invention. It should be understood that, for clarity and ease of illustration, the number, dimensions, proportions and shapes of elements are exaggerated. Moreover, dimensions, proportions and shapes of the same elements in the attached figures may differ.

A laser annealing method according to the invention provide transformation-scheduled regions, each of which is set to coextend with that portion of amorphous silicon which becomes a channel region of a TFT. This laser annealing method carries out irradiation of the laterally aligned transformation-scheduled regions with a laser beam one after another while the laser beam being laterally moved for lateral growth of a crystalline silicon film within each transformation-scheduled region.

This laser annealing method includes a lateral crystal forming process. In the lateral crystal forming process, a cw laser beam is moved across each the laterally aligned transformation-scheduled regions along a lateral straight line perpendicular to a longitudinal axis of gate fins formed on a substrate with the associated seed-crystal zone as a starting point. This results in crystal growth to produce crystalline silicon out of amorphous silicon within each of the laterally aligned transformation-scheduled regions.

### Embodiments

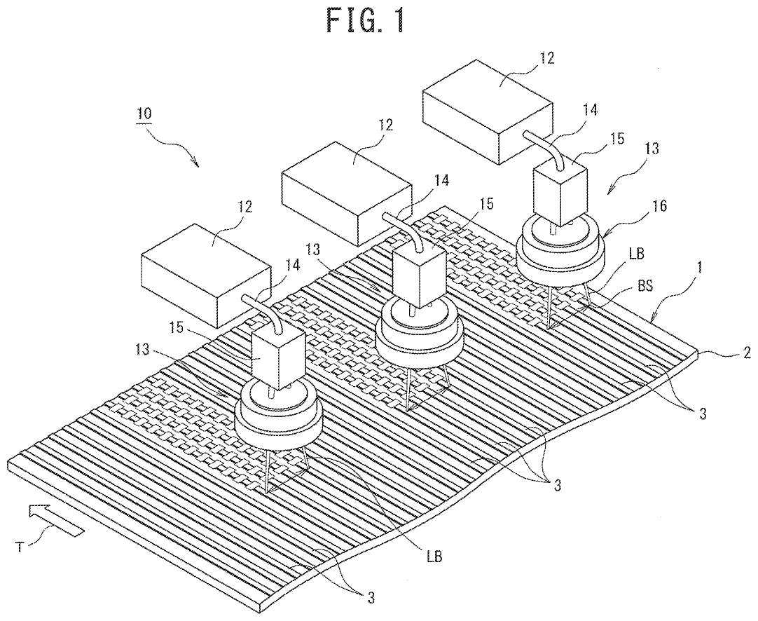

Hereinafter, one example of a workpiece, which is subject to a laser anneal of a laser annealing method according to one embodiment of the invention, and a laser annealing apparatus 10 used in the laser annealing method are described. Incidentally, for the convenience of illustration, FIG. 1 depicts a laser annealing apparatus with a gate insulator film 4 and an amorphous silicon film 5, which are later described, removed.

### Workpiece

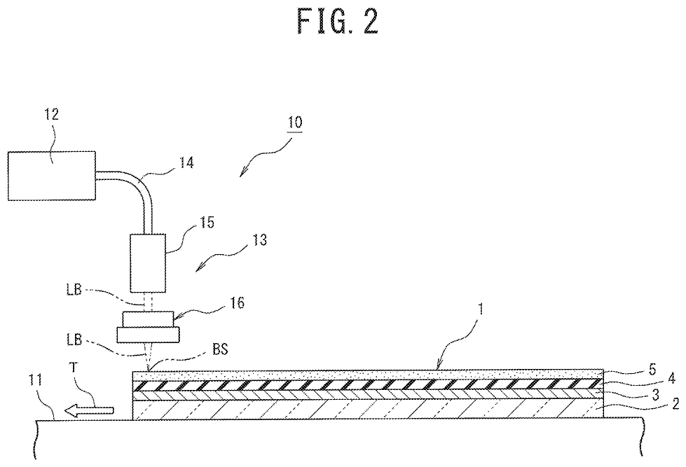

As depicted in FIGS. 1 and 2, a workpiece 1 includes a glass substrate 2, gate fins 3 formed on the surface of the glass substrate 2 in a way such that they extend along a longitudinal axis and are arranged in parallel, a gate insulator film 4 (see FIG. 2) on the gate fins 3 and over the glass substrate 2, and an amorphous silicon film 5 (see FIG. 2) deposited on the gate insulator film 4 to extend its entire surface. Moreover, the workpiece 1 will finally become a TFT substrate with built-in TFTs.

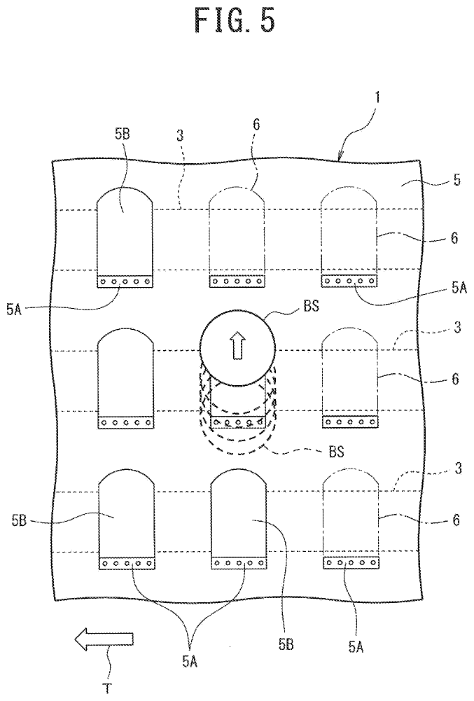

According to the present embodiment, the workpiece 1 is transported in a direction along the longitudinal axis of the gate fins 3 to carry out a laser anneal. As depicted in FIG. 5, each of substantially rectangular transformation-scheduled regions 6 is set to coextend with that portion of the amorphous silicon film 5 which extends over the associated one of the gate fins 3. The transformation-scheduled regions 6 will finally become channel regions of TFTs. The transformation-scheduled regions 6 are equal in number to TFTs to be formed along the lateral straight line perpendicular to the longitudinal axis of the gate fins 3.

### Configuration of Laser Annealing Apparatus

Hereinafter, the configuration of a laser annealing apparatus 10 according to an embodiment is described with reference to FIGS. 1 and 2. As depicted in FIG. 2, the laser annealing apparatus 10 includes a base 11, a laser source part 12, and a laser beam irradiation part 13.

In this embodiment, it is not the laser beam irradiation part 13 but the workpiece 1 that is moved during anneal processing. The base 11 is associated with a system for transporting workpieces. With the workpiece 1 placed on the base 11, the workpiece 1 is transported by the transporting system, not shown, in a transport (or scan) direction T. As depicted in FIGS. 1 and 2, the transport direction T is a direction parallel to the longitudinal axis of the gate fins 3.

The laser source part 12 includes a cw laser source for emitting a cw laser beam. The cw laser beam is herein used to include a concept of a laser beam emitted by a quasi-continuous-wave (quasi-cw) operation designed to continuously irradiate a target region. In other words, a laser beam may be emitted by a pulsed operation or a quasi-cw operation that allows a pulse interval shorter than the cooling time of a silicon thin film (amorphous silicon film) after being heated so that the silicon film can be irradiated with the next pulse before solidifying. The laser source part 12 may use various kinds of lasers such as a semiconductor laser, a solid-state laser, a liquid laser, and a gas laser.

The laser source part 12 and the laser irradiation part 13 are held above the base 11 with a support frame, not illustrated. The laser beam irradiation part 13 includes a scanner 15 and a fθ lens 16.

The laser source part 12 and the scanner 15 are connected with optical fibers 14. The optical fibers 14 deliver the cw laser beam emitted by the laser source part 12 to the scanner 15. Using a galvano mirror that is rotated, the scanner 15 can scan the cw laser beam LB, which is delivered by the optical fibers 14, around an axis by a predetermined angle.

The fθ lens 16 is used with a galvano mirror or polygon mirror to scan a laser beam in two dimensions. The lens distortion characteristic is used to scan the focused beam spot BS of the laser beam LB scanned by the mirror's constant velocity rotational motion at a uniform speed in linear motion on the focal plane.

As depicted in FIG. 1, in the laser annealing apparatus 10 according to the embodiment, the uniform linear motion of the beam spot BS of the laser beam LB passing through the fθ lens 16 is one-dimensional motion along a lateral straight line perpendicular to the longitudinal axis of the gate fins 3. The uniform linear motion may be one-dimensional motion along a straight line that is determined in consideration of the movement of the workpiece 1. The uniform linear motion of the beam spot BS of the laser beam LB may be one-dimensional motion along a straight line that is inclined to the lateral straight line perpendicular to the longitudinal axis of the gate fins 3 so that the beam spot BS will pass through each of the centers of the laterally aligned transformation-scheduled regions 6.

In the embodiment, the operation of the laser beam LB is set in a way such that the irradiation with the laser beam LB, in which the beam spot of the laser beam LB having passed through the fθ lens 16 moves along the lateral straight line perpendicular to the longitudinal axis of the gate fins 3, can be switched on or off. In detail, the laser source part 12 can be switched on or off depending on where the beam spot of the laser beam LB, which is being controlled by the scanner 15, is. As depicted in FIG. 5, a region, onto which the beam spot BS of the laser beam LB is projected, is a transformation-scheduled region 6. Moreover, the laser source part 12 is switched off at a location over the area bridging the adjacent two of the gate lines 3 to prevent the projection of the beam spot BS onto the amorphous film.

### Laser Annealing Method

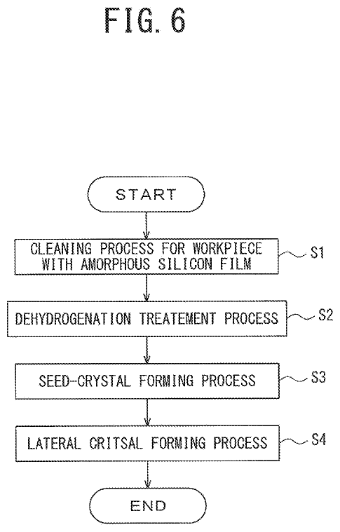

Referring now to FIGS. 1 to 10, a description about a laser annealing method according to an embodiment of the present invention follows. Hereinafter, the description proceeds taken in conjunction with the flow chart shown in FIG. 6.

The method commences with providing a workpiece 1 depicted in FIG. 2. There exist silicon dioxide (SiO₂) resulting from oxidation of amorphous silicon and particles (P) on the surface of an amorphous silicon film 5 that defines the top layer of the workpiece 1. To remove the silicon dioxide and particles, the method performs a cleaning process for cleaning the workpiece 1 (step S1). By performing the cleaning process, the silicon dioxide and particles are removed from the surface of the amorphous silicon film 5.

Next, the method performs a dehydrogenation treatment process within a dehydrogenation treatment furnace, not shown, for removing hydrogen from the workpiece 1 (step S2). Performing the dehydrogenation treatment process makes it possible for hydrogen (H) to leave the amorphous silicon film 5 formed to overlap the entire surface of the workpiece 1.

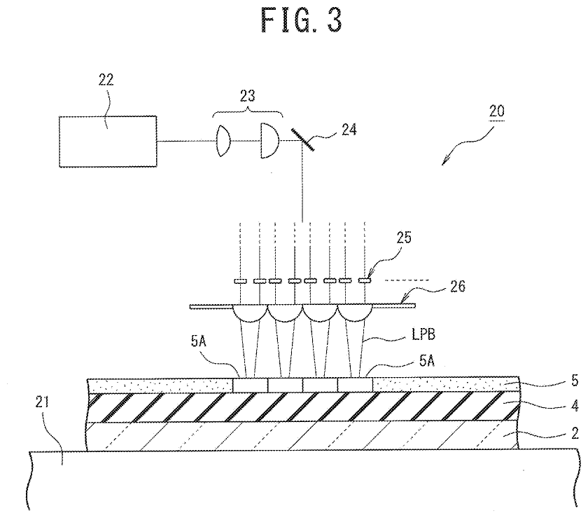

Subsequently, the method performs a seed crystal forming process, as depicted in FIG. 3, in which the workpiece 1 after the dehydrogenation treatment process is subject to a seed crystal forming process, which is carried out with an excimer laser irradiation apparatus 20 (step S3). The excimer laser irradiation apparatus 20 includes a base 21, an excimer laser source 22, a group of lenses 23, a mirror 24, a mask 25 and an array of micro lenses 26.

As depicted in FIG. 3, the excimer laser irradiation apparatus 20 irradiates the amorphous silicon film 5 on the workpiece 1 with multiple pulsed laser beams (LPB: laser pulsed beam). As depicted in FIG. 5, in the seed crystal forming process, a seed-crystal zone 5A is formed at a position proximate to the periphery of each transformation-scheduled region 6 that is set to coextend with that portion of the amorphous silicon film 5 which extends over one of the gate fins 3 and it is aligned with the transformation-scheduled region 6 in the lateral straight line perpendicular to the longitudinal axis of the gate fins 3. The amorphous silicon film 5 is irradiated with a laser beam for seed crystal formation which is, in this example, in the form of a pulsed laser beam LPB to form the seed-crystal zone 5A filled with microcrystalline silicon at the position which does not overlap the gate fin 3. In this seed crystal forming process, the seed-crystal zone 5A is formed at the position proximate to the periphery of each of the transformation-scheduled regions 6 within an area for TFTs.

Next, after the above-mentioned seed crystal forming process, the workpiece 1 is placed on the top of the base 11 of the laser annealing apparatus 10 as depicted in FIG. 2. The workpiece transporting system mentioned before (not shown) transports the workpiece 1 in the transport direction T at a constant velocity. Under a situation like this, as depicted in FIGS. 1 and 2, the method includes a lateral crystal forming process in which a laser beam LB from a laser beam irradiation part 13 moves along the lateral straight line perpendicular to the longitudinal axis of the gate fins 3 (step S4).

In this case, the surface of the amorphous silicon film 5 is irradiated with the laser beam LB in the form of a cw laser beam that can be moved with the seed-crystal zone 5A proximate the associated transformation-scheduled region 6 as a starting point. This lateral crystal forming process allows selective crystal growth to produce a pseudo single crystalline silicon film 5B, as a crystalline silicon film, out of the amorphous silicon film 5 within the transformation-scheduled region 6.

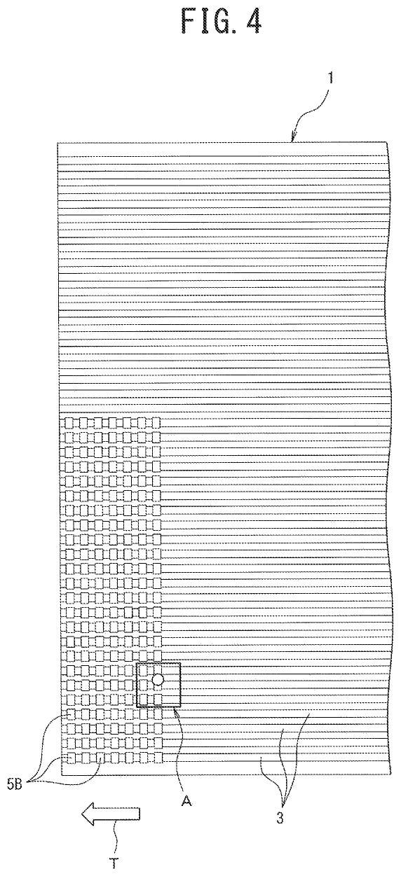

This laser beam LB is a spot laser beam. As depicted in FIG. 5, its incident beam is shaped to result in a beam spot BS, with its diameter nearly equal to the width of each of the transformation-scheduled regions 6, on the amorphous silicon film 5. As readily seen from FIG. 5, after completion of lateral crystal growth within one transformation-scheduled region 6, the adjacent one of the laterally aligned transformation-scheduled regions 6 is subject to a laser anneal with the laser beam LB. In this manner, the lateral crystal forming process is conditioned to move the laser beam LB, in the form of a cw laser beam, across the transformation-scheduled regions 6 aligned in the lateral straight line perpendicular to the longitudinal axis of the gate fins 3 to intermittently perform laser irradiation. This results in transformation to pseudo single crystalline silicon film 5B within each of the transformation-scheduled regions 6 as depicted in FIGS. 1 and 4.

In this lateral crystal forming process, suitable conditions are set for laser irradiation with the laser beam LB to cause transformation of the amorphous silicon film 5 within each transformation-scheduled region 6 to the pseudo single crystalline silicon film 5B as the crystalline silicon film.

In the laser annealing method according to the embodiment, because the seed crystals formed within each seed-crystal zone 5A are a single source of the following lateral crystal growth, only forming the seed crystals with good accuracy within the seed-crystal zone 5A in the seed crystal forming process suffice in order for allowing a reduction in the accuracy of irradiation position of laser beam LB in the lateral crystal forming process. This makes it possible to allow lateral crystal growth only in an area for fabrication of TFTs.

In the laser annealing method according to the embodiment, it is no longer necessary to shape a laser beam having a line spot shape suitable for lateral crystal growth in the lateral crystal forming process, making it possible to form a crystalline silicon film at low cost because of no need for a long cylindrical lens.

In addition, in the embodiment, with the workpiece 1 being transported in the transport direction T, the laser beam LB moves along the lateral straight line perpendicular to the longitudinal axis of the gate fins 3. Because the velocity at which the laser beam LB moves is fast enough as compared to the velocity at which the workpiece 1 is transported in the transport direction T, the deviations of the laterally aligned regions practically occupied by pseudo single crystalline films 5B from the lateral straight line perpendicular to the longitudinal axis of the gate fins 3 are negligible.

The deviations may be not negligible. In this case, according to the present invention, the beam spot BS may move diagonally along a diagonal straight line angled to the lateral straight line perpendicular to the longitudinal axis of the gate fins 3 so that the beam spot BS will pass through each of the centers of the laterally aligned transformation-scheduled regions 6.

### Other Embodiments

Having described preferred embodiments, the descriptions and the accompanying drawings are not to be understood to limit the scope and sprit of the invention. Many transformations and variations will be apparent to those of ordinary skill in the art without departing from the scope and sprit of the described embodiments.

In the foregoing preferred embodiments, a pseudo-single crystalline silicone film 5B is formed as crystalline silicon film, but a polycrystalline silicon film may be obtained using crystal growth from a seed-crystal zone. In this case as well, a high-quality polycrystalline film can be obtained using a seed-crystal zone as a starting point.

In the foregoing preferred embodiments, the scanner 15 is implemented as an optical system including a galvano mirror, but it may be implemented as a system configured to affect the optical path of the laser beam LB.

### LIST OF REFERENCE NUMERALS

BS Beam Spot
LB Laser Beam
LPB Pulsed Laser Beam
1 Workpiece
2 Glass Substrate
3 Gate Fins
4 Gate Insulator Layer
5 Amorphous Silicon Film
6 Transformation-scheduled Regions
10 Laser Annealing Apparatus
11 Base
12 Laser Source Part
13 Laser Beam Irradiation Part
14 Optical Fiber
15 Scanner
16 Fθ Lens
20 Excimer Laser Irradiation Apparatus
21 Base
22 Excimer Laser Source
23 Lens Array
24 Mirror
25 Mask
26 Micro Lens Array

1. A laser annealing method of transforming amorphous silicon of a film, which overlaps a workpiece including gate fins formed on a substrate in a way such that they extend along a longitudinal axis and are arranged in parallel, to crystalline silicon, the laser annealing method comprising:
providing the workpiece having a seed-crystal zone for microcrystalline silicon at a location proximate to the periphery of and aligned with one of transformation-scheduled regions, each of which is set to coextend with that portion of the amorphous silicon which extends over one of the gate fins, in a lateral straight line perpendicular to the longitudinal axis, and
a lateral crystal forming process of carrying out selective crystal growth by moving a continuous wave laser beam along the lateral straight line with the seed-crystal zone as a starting point to irradiate the amorphous silicon to grow crystalline silicon within the transformation-scheduled region.

2. The laser annealing method as claimed in claim 1, wherein, in the lateral crystal forming process, the continuous wave laser beam is a spot laser beam whose incident beam is shaped to result in a beam spot on the surface of the amorphous silicon film.

3. The laser annealing method as claimed in claim 2, wherein, in the lateral crystal forming process, the beam spot of the continuous wave laser beam moves through the transformation-scheduled regions arranged in the lateral straight line to intermittently irradiate the amorphous silicon.

4. The laser annealing method as claimed in claim 1, further comprising:
a seed crystal forming process in which the seed-crystal zone is laser irradiated with a laser beam for seed crystal formation to grow microcrystalline silicon within the seed-crystal zone prior to the lateral crystal forming process.

5. The laser annealing method as claimed in claim 4, wherein, in the seed crystal forming process, pulsed laser beams shaped with microlens arrays, each containing multiple micro lenses in a rectangular array, are used for laser irradiation.

6. A laser annealing apparatus for transforming amorphous silicon of a film, which overlaps a workpiece including gate fins formed on a substrate in a way such that they extend along a longitudinal axis and are arranged in parallel, to crystalline silicon, the laser annealing apparatus comprising:
a laser source part operative in a continuous wave mode to emit a continuous wave laser beam, and
a laser beam irradiation part operative to move the beam spot of the continuous wave laser beam along a lateral straight line perpendicular to the longitudinal axis to grow crystalline silicon within a selected one of transformation-scheduled regions, each of which is set to coextend with that portion of the amorphous silicon which extends over one of the gate fins.

7. The laser annealing apparatus as claimed in claim 6, wherein the laser beam irradiation part includes a scanner operative to move the laser beam along the lateral straight line.

8. The laser annealing apparatus as claimed in claim 6, wherein the laser beam irradiation part is operative to move the beam spot of the laser beam through the transformation-scheduled regions which are aligned in the lateral straight line.

9. The laser annealing apparatus as claimed in claim 6, wherein
the substrate has a seed-crystal zone for microcrystalline silicon at a location proximate to the periphery of and aligned with one of the transformation-scheduled regions in the lateral straight line, and
the laser beam irradiation part is operative to start laser irradiation with the continuous wave laser beam with the seed-crystal zone as a starting point.
